(19) United States
(12) Patent Application Publication
(10) Pub. No.: US 2006/0183036 A1
(43) Pub. Date: Aug. 17, 2006

(54) Method of forming film pattern, method of manufacturing device, electro-optical device, and electronic apparatus

(75) Inventors: Tomoki Sakashita, Chino (JP); Katsuyuki Moriya, Azumino (JP); Toshimitsu Hirai, Chino (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/350,372

(22) Filed: Feb. 8, 2006

(30) Foreign Application Priority Data
Feb. 17, 2005 (JP) 2005-040126
Nov. 14, 2005 (JP) 2005-328485

(51) Int. Cl. G03F 1/00

(52) U.S. Cl. 430/6

(57) ABSTRACT

A method of forming a film pattern by disposing a functional liquid on a substrate includes: forming banks corresponding to the film pattern on the substrate; forming irregularities on bottoms between the banks by using the banks as a mask; and disposing the functional liquid between the banks and on the bottoms formed with the irregularities.

### RELATED APPLICATIONS

This application claims priority to Japanese Patent Application Nos. 2005-040126 filed Feb. 17, 2005 and 2005-328485 filed Nov. 14, 2005 which are hereby expressly incorporated by reference herein in their entirety.

### BACKGROUND

1. Technical Field

The present invention relates to a method of forming a film pattern, a method of manufacturing the device, an electro-optical device, and an electronic apparatus.

2. Related Art

Devices having wiring lines, such as electronic circuits or integrated circuits, are manufactured by using a photolithography method, for example. The photolithography method is used to apply a photosensitive material, which is called a resist, on a substrate on which a conductive film is applied beforehand, irradiate and develop a circuit pattern, and etch the conductive film according to a resist pattern so as to form a wiring pattern of a thin film. However, the photolithography method requires large-size equipment, such as a vacuum apparatus, or a complicated process, and only a small percentage of the materials are used, causing high production cost and waste of materials.

On the other hand, there has been suggested a method of forming a wiring pattern on a substrate by using a liquid droplet discharging method in which liquid material is discharged from a liquid droplet discharging head in the shape of liquid droplets, that is, a so-called inkjet method (for example, see U.S. Pat. No. 5,132,248). In this method, ink for formation of the wiring pattern, which is a functional liquid in which conductive particles such as metal particles are dispersed, is directly applied on the substrate in a pattern, and is then converted into a thin conductive film pattern by performing a heat treatment and Laser irradiation for the ink. Therefore, the photolithography method is not needed, which simplifies the process and requires less raw material.

However, there is the following problem in the conventional method described above. When a functional liquid is disposed on the substrate so as to form a wiring pattern, if the substrate has not been subjected to any treatment, there is a possibility that the wettability required to form the pattern or the adhesion between the pattern and the substrate will be insufficient. For this reason, when a fine pattern is formed, some wiring lines are short-circuited, which does not allow a highly reliable device to be formed.

### SUMMARY

An advantage of some aspects of the invention is that it provides a method of forming a film pattern which is capable of consistently forming a fine film pattern with high performance, a device, a method of manufacturing a device, an electro-optical device, and an electronic apparatus.

According to an aspect of the invention, a method of forming a film pattern by disposing functional liquid on a substrate includes: forming banks corresponding to the film pattern on the substrate; forming irregularities on bottoms between the banks by using the banks as a mask; and disposing the functional liquid between the banks formed with the irregularities.

According to the invention, since the forming of the irregularities between the banks is conducted, the lyophilic property of a surface of the substrate is improved, and thus the functional liquid can be uniformly disposed on the substrate. In addition, due to the irregularities formed on the surface of the substrate, the contact area between the substrate and the film is increased, which improves the adhesion of the film. In addition, since the functional liquid for forming the film pattern is disposed between the banks formed on the substrate, it is possible to prevent the functional liquid from scattering around liquid droplets and to easily form the wiring pattern in a predetermined shape according to the shape of the banks.

Further, in the invention, it is preferable that the forming of the irregularities include etching a surface of the substrate by using the banks as a mask. In this case, preferably, surfaces of the banks are fluorinated before the forming of the irregularities.

According to the method, it is possible to easily form the minute irregularities on the surface of the substrate. In addition, by fluorinating the banks before forming the irregularities, the banks can have corrosion resistance with respect to an etchant.

Furthermore, in the invention, preferably, the functional liquid is rendered conductive by performing heat treatment or optical treatment. For example, the functional liquid can contain conductive particles. According to the method, since the film pattern can function as a wiring pattern, the method can be applied to various devices. In addition, by using red (R), green (G), and blue (B) ink materials or a material for forming a light-emitting element, such as an organic EL element, in addition to the conductive particles and organic silver compound, the method can be applied to manufacture an organic EL device, a liquid crystal display device having a color filter, or the like.

According to another aspect of the invention, a method of manufacturing a device includes forming a film pattern on a substrate by using the method of forming the film pattern described above.

According to the method, it is possible to obtain the device having the film pattern which is reliably adhered to the substrate and is capable of preventing the occurrence of a problem, such as circuit shortage.

Further, according to yet another aspect of the invention, an electro-optical device includes the device manufactured by using the method of manufacturing the device described above.

According to the invention, it is possible to obtain the electro-optical device and an electronic apparatus each of which has the film pattern capable of preventing the occurrence of a problem, such as circuit shortage.

### BRIEF DESCRIPTION OF THE DRAWINGS

The invention will be described with reference to the accompanying drawings, wherein like numbers reference like elements.

FIG. 1 is a perspective view schematically illustrating a liquid droplet discharging apparatus.

FIG. 2 is a view illustrating the principle of discharging liquid droplets according to a piezo system.

FIG. 3 is a flow chart illustrating a method of forming a film pattern according to an embodiment of the invention.

FIGS. 4A to 4E are process views illustrating an example of an order of forming a film pattern according to the embodiment of the invention.

FIGS. 5A to 5D are-process views illustrating an example of the order of forming a film pattern according to the embodiment of the invention.

FIGS. 6A and 6B are views illustrating an example of a plasma processing apparatus used in a residue treatment process.

FIG. 7 is a plan view illustrating a liquid crystal display device when viewed from a counter substrate side.

FIG. 8 is a cross-sectional view taken along the line VIII-VIII of FIG. 7.

FIG. 9 is an equivalent circuit diagram of a liquid crystal display device.

FIG. 10 is a partially enlarged sectional view of the liquid crystal display device.

FIG. 11 is an exploded perspective view illustrating a non-contact card medium.

FIGS. 12A to 12C are views illustrating specific examples of an electronic apparatus according to the invention.

### DESCRIPTION OF EXEMPLARY EMBODIMENTS

Hereinafter, a method of forming a film pattern and a method of manufacturing a device according to an embodiment of the invention will be described with reference to the accompanying drawings. In the embodiment, a case will be described as an example in which wiring pattern forming ink is discharged from discharging nozzles of a liquid droplet discharging head in the shape of liquid droplets by using a liquid droplet discharging method, the wiring pattern forming ink including a material which has conductivity by, for example, heat treatment, and thus a wiring pattern (film pattern) composed of a conductive film is formed.

First, an ink to be used will be described. The ink corresponds to functional liquid of the invention. The functional liquid refers to solution capable of forming a film (functional film) having a specific function by making film components contained in liquid formed as a film. As the function, there are various functions such as electrical and electronic functions (conductivity, insulation, piezoelectricity, superconductivity, dielectricity, etc.), an optical function (photoselective absorption, reflectivity, polarization, photoselective transmitivity, non-linear optical property, luminescence such as fluorescence or phosphorescence, photochromic property, etc.), a magnetic function (hard magnetism, soft magnetism, non-magnetism, magnetic permeability, etc.), a chemical function (adsorption, desorption, catalyst, absorption, ion conductivity, oxidation-reduction, electrochemical property, electrochromic property, etc.), a mechanical function (abrasion resistance, etc.), a thermal function (thermal conductivity, thermal isolation, infrared radioactivity, etc.), a biological function (bio-compatibility, anti-thrombosis, etc.). In the present embodiment, in order to form the wiring pattern, for example, a wiring pattern forming ink containing conductive particles is used as the functional liquid (ink).

The wiring pattern forming ink which is a liquid material is composed of dispersion solution, in which conductive particles are dispersed into the dispersion medium, or solution, in which organic silver compound is dispersed into solvent (dispersion medium). The conductive particles include, for example, metal particles containing one of gold, silver, copper, aluminum, palladium, and nickel, oxides thereof, particles of conductive polymer or superconductor, etc. These conductive particles may be coated with organic materials so as to improve dispersibility. The diameters of the conductive particles are preferably in the range of 1 nm to 0.1 μm. If the diameters of the conductive particles are more than 0.1 μm, there is a possibility that nozzles of liquid droplet discharging heads will be blocked, which will be described later. Also, if the diameters of the conductive particles are less than 1 nm, the volume ratio of the coating material to the conductive particles becomes large, resulting in a large amount of organic matter in an obtained film.

A preferable dispersion medium is one that can disperse the conductive particles without blockage. For example, the dispersion medium may include water, alcohols such as methanol, ethanol, propanol, butanol, hydrocarbon compounds such as n-heptane, n-octane, decane, dodecane, tetradecane, toluene, xylene, cymene, durene, indene, dipentene, tetrahydronaphthalene, decahydronaphthalene, cyclohexylbenzene, etc., ether compounds such as ethylene glycol dimethyl ether, ethylene glycol diethyl ether, ethylene glycol methylethyl ether, diethylene glycol dimethyl ether, diethylene glycol diethyl ether, diethylene glycol methylethyl ether, 1,2-dimethoxyethane, bis(2-methoxyethyl)ether, p-dioxane, etc., polar compounds such as propylene carbonate, γ-butyrolactone, N-methyl-2-pyrrolidone, dimethyformamide, dimethylsulfoxide, cyclohexanone, etc. Of these compounds, from the view point of the dispersibility of particles and the stability of dispersion solution and applicability of the compounds to the liquid droplet discharging method, the dispersion medium is preferably water, alcohol, hydrocarbon compounds, and ether compounds, more preferably, water and hydrocarbon compounds.

The surface tension of the dispersion solution for the conductive particles is preferably within a range of 0.02 to 0.07 N/m. When liquid is discharged by using the liquid droplet discharging method, if the surface tension is less than 0.02 N/m, flight irregularity may easily occur because the wettability of the ink composition with respect to nozzle surfaces increases. In contrast, if the surface tension is more than 0.07 N/m, it is difficult to control the amount of discharge or discharge timing due to the irregular shapes of the meniscus at the leading edge of the nozzle.

In order to adjust the surface tension, it is preferable to add a very small amount of fluorine, silicon, or non-ionic surface tension conditioning agent within a range such that the contact angle of the dispersion solution of the substrate is not significantly lowered. The non-ionic surface tension conditioning agent assists to improve regularity of a film and prevent minute irregularity of the film from occurring by improving the wettability of the liquid with respect to the substrate. The surface tension conditioning agent may contain organic compounds such as alcohol, ether, ester, or ketone, if necessary.

The viscosity of the dispersion solution is preferably in the range of 1 to 50 mPa·s. When liquid droplet material is discharged as liquid droplets by using the liquid droplet discharging method, if the viscosity of the dispersion solution is less than 1 mPa·s, the circumferences of the nozzles may be easily contaminated due to outflow of the ink. In contrast, if the viscosity of the dispersion solution is more than 50 mPa·s, the blockage frequency of nozzle holes become high, as a result, becoming difficult in smoothly discharging the liquid droplets.

The substrate to be formed with the wiring pattern includes, for example, a glass, a quartz glass, a Si wafer, a plastic film, a metal plate. Further, the substrate includes a glass, a quartz glass, a Si wafer, a plastic film, or a metal plate, on which a semiconductor film, a metal film, a dielectric film, or an organic film is formed as a base layer.

Here, a discharge technique of the liquid droplet discharging method may include a charging control system, a pressure vibration system, an electric-mechanical conversion system, an electric-thermal conversion system, an electrostatic suction system, etc. The charging control system is to provide charge to material by using charging electrodes and to control the flight direction of the material by using deflecting electrodes so as to discharge the material from the nozzles. In addition, the pressure vibration system is to apply very high pressure of about 30 kg/cm² to material so as to discharge the material toward leading edges of the nozzles. In this case, when a control voltage is not applied, the material goes straight to be discharged from the nozzles. If the control voltage is applied, an electrostatic repulsive force between materials is produced, and accordingly, the materials are scattered and are not discharged from the nozzles. In addition, the electric-mechanical conversion system, which uses a property that piezoelectric elements are deformed when an electric pulse signal is applied thereto, is to apply a pressure to a space, in which materials are stored, through a flexible material by deforming the piezoelectric elements, and to press the materials out of the space so as to discharge the materials from the nozzles.

In addition, the electric-thermal conversion system is to produce bubbles by rapidly vaporizing materials using a heater provided in the space in which the materials are stored, and to discharge the materials stored in the space by using pressure of the bubbles. The electrostatic suction system is to apply a small pressure to the space in which materials are stored so as to form meniscus of materials on nozzles, and to extract the materials by applying an electrostatic attraction force. In addition to the above-mentioned systems, techniques, such as a system where the change of viscosity of fluid due to an electric field is used and a system where discharged spark is used, can also be applied. The liquid droplet method is advantageous in that it is possible to reduce the wasted amount of materials and to dispose a desired amount of materials at a desired position. In addition, one droplet of a liquid material discharged according to the liquid droplet discharging method has a weight in the range of, for example, 1 to 300 nanograms.

Next, a description will be provided of a device manufacturing apparatus used when the device according to the invention is manufactured. As the device manufacturing apparatus, a liquid droplet discharging apparatus (inkjet apparatus), in which liquid droplets are discharged from the liquid droplet discharging head onto the substrate so as to manufacture the device, is used.

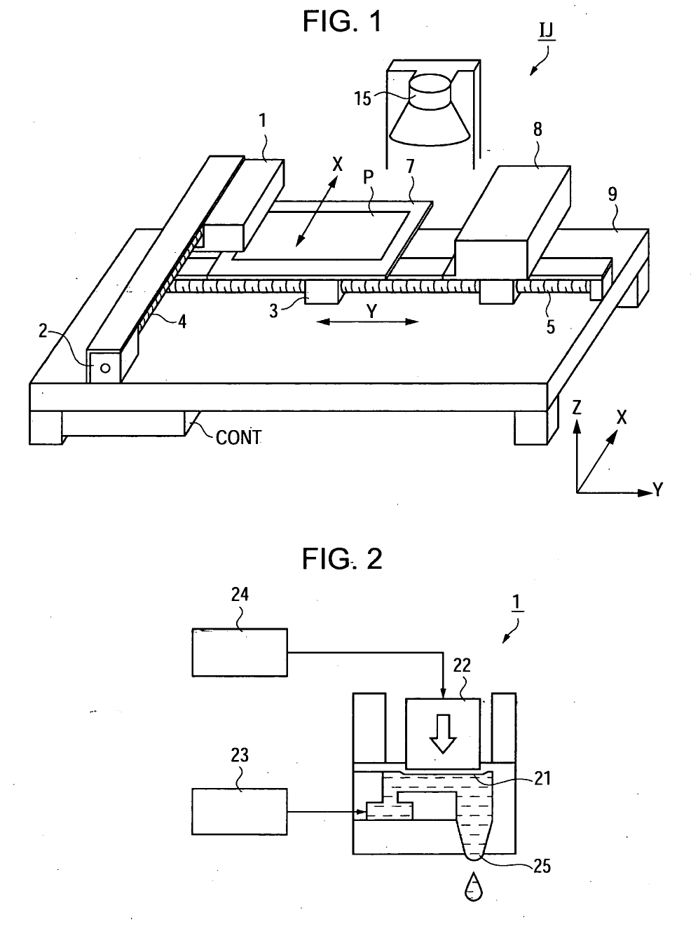

FIG. 1 is a perspective view schematically illustrating the construction of a liquid droplet discharging apparatus IJ. Referring to FIG. 1, the liquid droplet discharging apparatus IJ includes a liquid droplet discharging head 1, an X axis direction driving shaft 4, a Y axis direction guide shaft 5, a controller CONT, a stage 7, a cleaning mechanism 8, a base station 9, and a heater 15.

The stage 7 supports a substrate P on which ink (liquid material) is provided by the liquid droplet discharging apparatus IJ, and includes a fixture (not shown) for fixing the substrate P at a reference position.

The liquid droplet discharging head 1 is a multi-nozzle-type liquid droplet discharging head having a plurality of discharging nozzles and a longitudinal direction thereof is the X axis direction. The plurality of discharging nozzles is positioned in a row on a lower side of the liquid droplet discharging head 1 at predetermined intervals in the X direction. The ink containing the above-described conductive particles is discharged onto the substrate P supported on the stage 7 from the discharging nozzles of the liquid droplet discharging head 1.

An X axis direction driving motor 2 is connected to the X axis direction driving shaft 4. The X axis direction driving motor 2 is, for example, a stepper motor and rotates the X axis direction driving shaft 4 when an X axis direction driving signal is supplied from the controller CONT. When the X axis direction driving shaft 4 rotates, the liquid droplet discharging head 1 moves in the X axis direction.

The Y axis direction guide shaft 5 is fixed so as not to move with respect to the base station 9. The stage 7 includes a Y axis direction driving motor 3. The Y axis direction driving motor 3 is, for example, a stepper motor and moves the stage 7 in the Y axis direction when a Y axis direction driving signal is supplied from the controller CONT.

The controller CONT supplies a voltage to control the amount of discharge of the liquid droplets to the liquid droplet discharging head 1. In addition, the controller CONT supplies a driving pulse signal, which controls the movement of the liquid droplet discharging head 1 in the X axis direction, to the X axis direction driving motor 2 and a driving pulse signal, which controls the movement of the stage 7 in the Y axis direction, to the Y axis direction driving motor 3.

The cleaning mechanism 8 cleans the liquid droplet discharging head 1. The cleaning mechanism 8 includes a Y axis direction driving motor (not shown). The cleaning mechanism 8 moves along the Y axis direction guide shaft 5 by driving the Y axis direction driving motor. The movement of the cleaning mechanism 8 is controlled by the controller CONT.

The heater 15 is to thermally treat the substrate P by using a lamp annealing, for example, and vaporizes and dries the solvent contained in the ink applied on the substrate P. The power on/off of the heater 15 is controlled by the controller CONT.

The liquid droplet discharging apparatus IJ discharges liquid droplets onto the substrate P while relatively scanning the stage 7 supporting the liquid droplet discharging head 1 and the substrate P. In the following description, the Y axis direction is referred to as a scanning direction and the X axis direction perpendicular to the Y axis direction is referred to as a non-scanning direction. Accordingly, the discharging nozzles of the liquid droplet discharging head 1 are arranged at predetermined intervals in the X axis direction, that is, the non-scanning direction. In addition, while it is shown in FIG. 1 that the liquid droplet discharging head 1 is disposed to be perpendicular to a traveling direction of the substrate P, the head 1 may intersect the traveling direction of the substrate P by adjusting the angle of the liquid droplet discharging head 1. By adjusting the angle of the liquid droplet discharging head 1, the pitch between nozzles can be adjusted.

In addition, the distance between the substrate P and a nozzle plane may be arbitrarily adjusted.

FIG. 2 is a view illustrating the principle of discharging liquid droplets according to a piezo system. Referring to FIG. 2 a piezo element 22 is provided adjacent to a liquid chamber 21 storing the liquid material (wiring pattern forming ink and functional liquid). The liquid material is supplied to the liquid chamber 21 by a liquid material supply system 23 including a material tank storing the liquid material. The piezo element 22 is connected to a driving circuit 24. A voltage is applied to the piezo element 22 through the driving circuit 24 so as to deform the piezo element 22, and thus the liquid chamber 21 is deformed to discharge the liquid material from a nozzle 25. In this case, by changing the magnitude of an applied voltage, the amount-of distortion of the piezo element 22 is controlled. In addition, by changing the frequency of the applied voltage, the speed of distortion of the piezo element 22 is controlled. Since the liquid material is not heated when the liquid droplet is discharged according to the piezo system, there is an advantage in that the composition of the liquid material is barely affected.

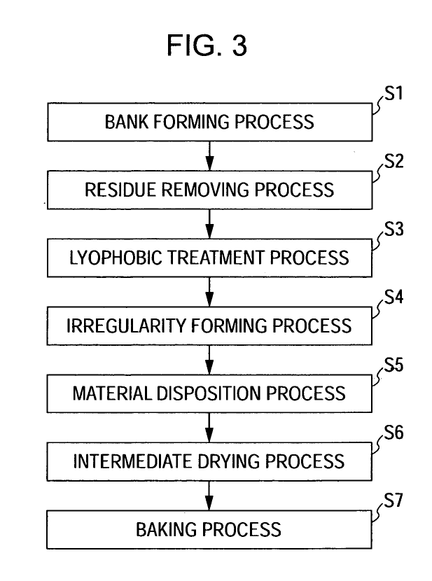

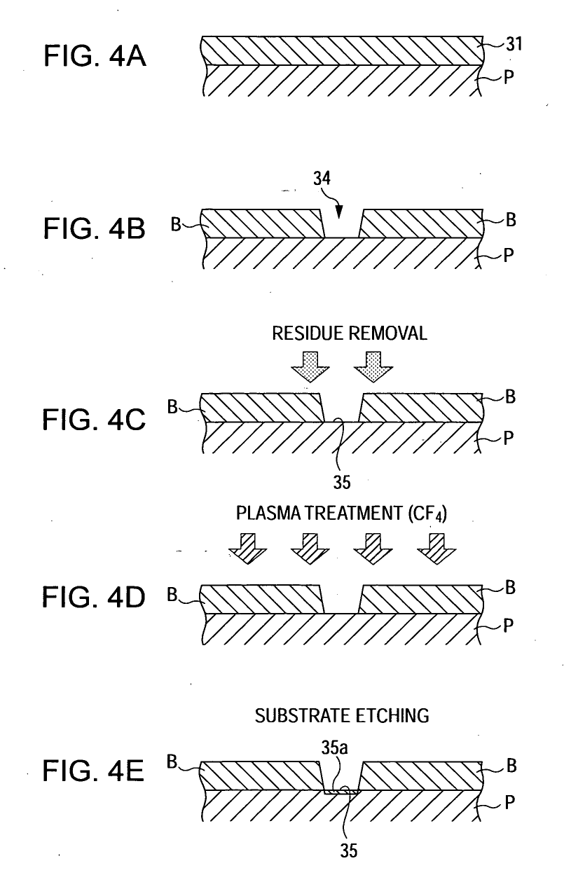

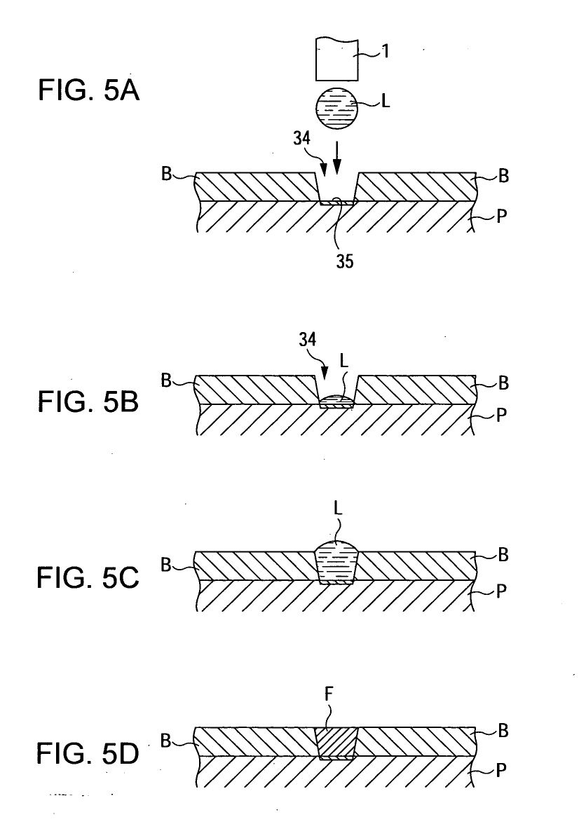

Next, a method of forming a wiring pattern according to an embodiment of the invention will be described with reference to FIGS. 3, 4A to 4E, 5A to 5D. FIG. 3 is a flow chart illustrating an example of a method of forming a wiring pattern according to the present embodiment, and FIGS. 4A to 4E and 5A to 5D are schematic views showing an order of forming the wiring pattern.

As shown in FIG. 3, in a method of forming a wiring pattern according to the present embodiment, the above-described ink for forming the wiring pattern is disposed on a substrate and a conductive wiring pattern is formed on the substrate. Specifically, the method generally includes a bank forming process S1 for forming banks according to the wiring pattern on the substrate, a residue removing process S2 for removing residue between the banks, a lyophobic treatment process S3 for performing lyophobic treatment on the banks, irregularity forming process S4 for forming minute irregularities on bottoms (e.g., the substrate surface) between the banks by using the banks as a mask, a material disposition process S5 for disposing the ink between the banks formed with the irregularities, an intermediate drying process S6 for removing at least some of liquid components of the ink, and a baking process S7.

Hereinafter, the respective processes will be described in detail. A glass substrate is used as the substrate P in the present embodiment.

Bank Forming Process

First, the banks are formed on the substrate P, as shown in FIG. 4A. The banks function as partitions. The formation of the banks may be performed by using a photolithography method, a printing method, or other methods. If the photolithography method is used, as shown in FIG. 4A, an organic photosensitive material 31 is applied onto the substrate P in accordance with the height of the banks by using a specific method such as spin coat, spray coat, roll coat, die coat, or deep coat, and then a resist layer is applied on the material 31. Then, a mask is placed on the resist layer in accordance with the shape of the banks (wiring pattern) so as to expose and develop the resist layer, thereby leaving only a resist in accordance with the shape of the banks. Lastly, an etching process is performed to remove the bank material in portions other than the mask. The banks (protruding parts) may include two layers, which are composed of an inorganic lower layer and an organic upper layer, or more. As shown in FIG. 4B, the banks B are formed so as to surround a region where the wiring pattern is to be formed.

The bank formation material may be a material having a lyophobic property with respect to a liquid material, or may be an insulation material which can have the lyophobic property (be fluorinated) by performing plasma treatment and has good adhesion with respect to a substrate and can be easily patterned by using a photolithography method, as will be described later. For example, organic materials, such as acryl resin, polyimide resin, olefin resin, phenol resin, or melamine resin, may be used. In addition, from the point of view of the heat-resistance, the inorganic materials may be used as the bank forming material. When the bank formation material includes the inorganic materials, since the heat-resistance of the banks B becomes high and the difference in the coefficients of thermal expansion between the banks B and the substrate P becomes small, the banks B may be prevented from being deteriorated due to heat being generated when the functional liquid is dried, and thus the film pattern has a desired shape. The inorganic bank material includes, for example, high molecular inorganic materials or photosensitive inorganic materials containing silicon with a skeleton of polysilazane, polysiloxane, siloxane resist, or polysilane resist, a spin-on-glass film containing one of silica glass, alkylsiloxane polymer, alkylsilsequioxane polymer, alkylsilsequioxane polymer hydride, and polyaryl ether, a diamond film, an amorphous carbon fluoride film, etc. In addition, the inorganic bank material may include, for example, aerogel, porous silica, etc. In the present embodiment, an organic material, such as acrylic resin, is used as the bank formation material.

Further, an HMDS treatment, as a surface reforming treatment before the bank material is applied, may be performed on the substrate P. The HMDS treatment is a method of applying hexamethyldisilazane ((CH₃)₃SiNHSi(CH₃)₃) in the form of vapor. Thereby, a HMDS layer, as an adhesion layer to improve the adhesion between the banks and the substrate P, can be formed on the surface of the substrate P.

Residue Removing Process

When the banks B are formed on the substrate P, fluoric acid treatment is performed as shown in FIG. 4C. The fluoric acid treatment is to perform etching with, for example, 2.5% fluoric acid aqueous solution so as to remove organic materials between the banks B. In the fluoric acid treatment, the HMDS layer, organic bank material(s) remaining on bottoms 35 of trenches 34 formed between the banks B, and the like are removed by using the banks B as a mask.

Here, the residue remaining on the bottoms 35 between the banks B may not be completely removed by the fluoric acid treatment. In addition, resist (organic material) in forming the banks B may remain on the bottoms 35 between the banks B. Therefore, in order to remove the residue which is an organic material (resist or HMDS) remaining on the bottoms 35 between the banks B when forming the banks B, the residue removing treatment is performed on the substrate P.

The residue removing treatment may be an ultraviolet (UV) irradiation treatment for removing the residue by irradiating an ultraviolet ray, an O₂ plasma treatment using oxygen as a process gas in an air atmosphere, or the like. Here, the O₂ plasma treatment is performed.

In the O₂ plasma treatment, oxygen in a plasma state is irradiated from a plasma discharge electrode onto the substrate P. The conditions for the O₂ plasma treatment are, for example, the plasma power in the range of 50 to 1000 W, the flow rate of oxygen in the range of 50 to 100 ml/min, the relative moving speed of the substrate 1 with respect to the plasma discharge electrode in the range of 0.5 to 10 mm/sec, and the substrate temperature in the range of 70 to 90° C.

Further, if the substrate P is a glass substrate, the surface thereof has the lyophilic property with respect to the wiring pattern forming material; however, it is possible to increase the lyophilic property of the surface (bottoms 35) of the substrate P exposed between the banks B by performing the O₂ plasma treatment or ultraviolet irradiation treatment for removing the residue as in the present embodiment. Here, the O₂ plasma treatment or the ultraviolet irradiation treatment is preferably performed such that the contact angle of the bottom 35 between the banks B with respect to ink is less than 15°.

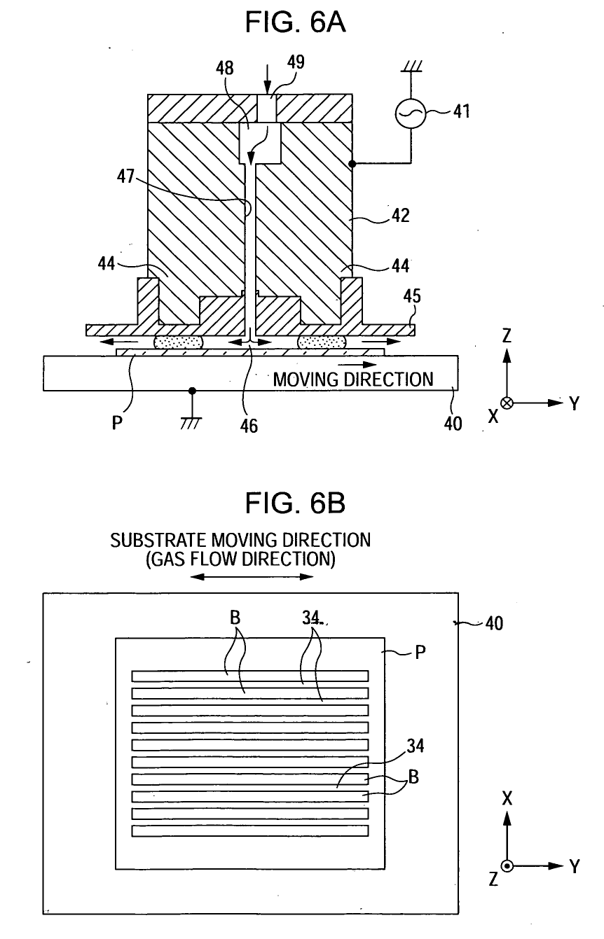

FIG. 6A is a view schematically illustrating an example of the construction of a plasma processing apparatus used in the O₂ plasma treatment. The plasma processing apparatus shown in FIG. 6A has an electrode 42, which is connected to an alternating-current power supply 41, and a sample table 40 serving as a ground electrode. The sample table 40 supports the substrate P which is a sample and can move in the Y axis direction. Below the electrode 42, two discharge generation units 44, which are parallel to each other and extend in the X axis direction perpendicular to the moving direction, and a dielectric member 45 which surrounds the discharge generation units 44 are provided. The dielectric member 45 prevents abnormal discharge of the discharge generation units 44. In addition, the lower surface of the electrode 42 including the dielectric member 45 has approximately a flat shape, and a small space (discharge gap) is provided between the substrates and the discharge generation units 44 and the dielectric member 45. A gas port 46 is provided in the center of the electrode 42, the gas port 46 forming a part of a process gas supply unit provided to be thin and long in the X axis direction. The gas port 46 is connected to a gas inlet 49 through a gas path 47 and an intermediate chamber 48.

A predetermined gas including a process gas ejected from the gas port 46 through the gas path 47 flows toward the front and rear sides of the moving direction (Y axis direction) and is exhausted to the outside from front and rear ends of the dielectric member 45. At the same time, a predetermined voltage supplied from the power supply 41 is applied to the electrode 42 so as to generate a gas discharge between the discharge generation units 44 and the sample table 40. In addition, plasma generated by the gas discharge allows excitation-activated species of the predetermined gas to be generated, and the entire surface of the substrate P having passed the discharge area is consecutively processed.

In the present embodiment, the predetermined gas is obtained by mixing oxygen (O₂), which is the process gas, with rare gas, such as helium (He) or argon (Ar), or inert gas, such as nitrogen (N₂), which easily starts the discharge in an air atmosphere and keeps discharging stably. In particular, when the oxygen is used as the process gas, the organic residue is removed (cleaned) or the lyophilic treatment is performed as described above. In addition, by performing the O₂ plasma treatment for, for example, an electrode of an organic. EL device, the work function of the electrode can be adjusted.

FIG. 6B is a view illustrating the substrate P supported on the sample table 40. Referring to FIG. 6B, a plurality of banks B and trenches 34 formed between the banks B extend in one direction (here, Y axis direction) on the substrate P. On the trenches 34 between the banks B, a wiring pattern whose longitudinal direction is the Y axis direction is formed. Further, in the present embodiment, the substrate P formed with the banks B is subjected to the O₂ plasma treatment under a state where the extended direction (Y axis direction) of the banks B is equal to the moving direction of the sample table 40. That is, in the plasma treatment of the present embodiment, while the substrate P moves in the Y axis direction which is the extended direction of the banks B, the predetermined gas including the process gas is supplied. In other words, the plasma treatment is performed under a state where the flow direction of the predetermined gas is equal to the extended direction of the banks B. Thereby, since the process gas uniformly spreads on the bottoms 35 (exposed portion of the substrate P) between the banks B, the plasma treatment can be easily performed.

Further, even though the substrate P moves in the present embodiment, it is possible to move the electrode 42 forming the part of the process gas supply unit or to move both the substrate P and the electrode 42.

Furthermore, even though the fluoric acid treatment is performed as a part of the residue removing process in the present embodiment, the fluoric acid treatment may not be performed because the residue on the bottoms 35 between the banks B can be sufficiently removed by the O₂ plasma treatment or the ultraviolet irradiation treatment. In addition, even though one of the O₂ plasma treatment or the ultraviolet irradiation treatment is performed to remove the residue, the O₂ plasma treatment or the ultraviolet irradiation treatment may be combined.

Lyophobic Treatment Process

Subsequently, as shown in FIG. 4D, the banks B are subjected to the lyophobic treatment so that the surfaces thereof have a lyophobic property. The lyophobic treatment may use a plasma process using, for example, tetrafluoromethane as a process gas in an air atmosphere (CF₄ plasma process). The conditions for the CF₄ plasma process are, for example, the plasma power in the range of 100 to 800 W, the flow rate of CF₄ in the range of 50 to 100 ml/min, the carrying speed of gas with respect to a plasma discharge electrode in the range of 0.5 to 1020 mm/sec, and the temperature of gas in the range of 70 to 90° C. In addition, as the process gas, other fluorocarbon gases may be used without being limited to tetrafluoromethane (CF₄). In addition, the banks B may be subjected to the lyophobic treatment by using fluorine compound or a material containing fluorine.

The lyophobic treatment allows a fluorine group to be introduced into resin forming the banks B, thereby allowing high lyophobic property to the banks B. By fluorinating the surface of the banks B, the banks B have corrosion resistance with respect to an etchant used in the subsequent irregularity forming process. In addition, even though the O₂ plasma treatment, which is the lyophobic treatment, may be performed before the banks B are formed, the O₂ plasma treatment is preferably performed after the banks B are formed because acrylic resin or polyimide resin is apt to be fluorinated (have lyophobic property) when the acrylic resin or the polyimide resin is subjected to pre-treatment using the O₂ plasma.

Further, even though the lyophobic treatment with respect to the banks B has more or less effect on the exposed portions, of the substrate P, between the banks B which have been subjected to the lyophobic treatment, since the fluorine group is not introduced into the substrate P by the lyophobic treatment, particularly if the substrate P is made of glass or the like, the lyophilic property, that is, the wettability of the substrate P is not substantially deteriorated. In addition, by forming the banks B with a lyophobic material (for example, a resin material having a fluorine group), the lyophobic treatment with respect to the banks B may be omitted. A resist containing a fluorine resin can be used as the material.

Irregularity Forming Process

Next, as shown in FIG. 4E, the substrate P is subjected to soft etching treatment by using the banks B as a mask, thereby forming a plurality of minute irregularities 35a on the bottoms 35 of the trenches 34 between the banks B. By the irregularities formed on the surface of the substrate P, the lyophilic property of the substrate P is increased, and the ink spreads easily when the ink is discharged into the trenches 34, and thus the ink can fill in the trenches 34 even more uniformly. In addition, since the plurality of minute irregularities 35a is formed on the surface of the substrate P, it is possible to increase the surface area where the film adheres to the substrate P the adhesion between the film and the substrate P. Moreover, since the wet spreading range (the landing diameter of the ink) changes due to the size of the irregularities (surface roughness Ra), the size of the irregularities can be set to a proper value according to the design demand. In the present embodiment, the surface roughness Ra of the bottom 35 formed with the irregularities 35a is in the range of 0.1 to 50 nm, for example.

Material Disposition Process

Next, by using the liquid droplet discharging method using the liquid droplet discharging apparatus IJ, the liquid droplets L of the wiring pattern forming ink are disposed between the banks B on the substrate P. Here, the ink (functional liquid) L, which is composed of organic silver compound used as a conductive material and diethylene glycol dimethyl ether used as solvent (dispersion medium), is discharged. In the material disposition process, as shown in FIG. 5A, the ink L containing the wiring pattern formatting material is discharged from the liquid droplet discharging head 1 in the form of liquid droplets. The discharged liquid droplets are disposed in the trenches 34 between the banks B on the substrate P, as shown in FIG. 5B. The liquid droplets can be discharged under the conditions of the ink weight in the range of 4 ng/dot and the ink speed (discharging speed) in the range of 5 to 7 m/sec. In addition, the liquid droplets are preferably discharged under an atmosphere of temperature of less than 60° C. and humidity of less than 80%. Accordingly, the liquid droplets can be consistently discharged without the discharging nozzles of the liquid droplet discharging head 1 being blocked.

At this time, since a region (that is, the trench 34), in which the wiring pattern is to be formed and into which the liquid droplets are to be discharged, is surrounded by the banks B, the liquid droplets L can be prevented from spreading beyond a predetermined area. In addition, since the banks B have the lyophobic property, even when some of the discharged liquid droplets move above the banks B, some of the discharged liquid droplets are repelled from the banks B so as to flow down into the trench 34 between the banks B. In addition, since the bottoms 35 of the trenches 34 on which the substrate P is exposed have the lyophilic property, the discharged liquid droplets smoothly spread in the bottoms 35, and accordingly, the ink is uniformly disposed in the predetermined position.

Intermediate Drying Process

After the liquid droplets are discharged onto the substrate P, dry treatment is performed to remove the dispersion medium and secure a thickness of the film, if necessary. The dry treatment can be performed by using, for example, a typical hot plate or electric furnace for heating the substrate P, or lamp annealing. A light source used for the lamp annealing may include an infrared lamp, a xenon lamp, a YAG laser, an argon laser, a carbon gas laser, an excimer laser using XeF, XeCl, XeBr, KrF, KrCl, ArF, or ArCl, etc., but not limited thereto. The power of these light sources is generally used within a range of 10 to 5000 W. In the embodiment, the power is sufficient if it is within a range of 100 to 1000 W. In addition, the intermediate drying process and the above-described material disposition process may be repeatedly performed so as to stack a plurality of liquid droplet layers of the liquid material such that a thick wiring pattern (film pattern) is formed, as shown in FIG. 5C.

Baking Process

For the conductive material after the discharging process has been performed, in the case of, for example, organic silver compound, in order to obtain the conductivity, it is necessary to perform heat treatment and remove organic components of the organic silver compound so as to have silver particles remaining in the organic silver compound. Accordingly, the substrate P after the discharging process is subjected to heat treatment and/or optical treatment.

The heat treatment and/or optical treatment are typically performed in the air, but may be performed in an inert gas atmosphere such as nitrogen, argon or helium, if necessary. The treatment temperature in the heat treatment and/or optical treatment is properly determined in consideration of a boiling point (vapor pressure) of the dispersion medium, the kind or pressure of atmosphere gases, thermal behavior of particles such as dispersibility or oxidization, the presence or amount of coating material, heat-resistant temperature of base material, etc. For example, removal of the organic material of the organic silver compound requires baking at about 200° C. In addition, if the substrate P is formed of plastic or the like, it is preferable to perform the heat treatment and/or optical treatment at room temperature or higher and 100° C. or less. According to the above-described processes, the conductive material (organic silver compound) after the discharging process has been performed includes the silver particles, the conductive material is changed to a conductive film (wiring pattern) F, as shown in FIG. 5D.

Further, when the liquid droplets are stacked so as to form a plurality of layers, after the first liquid droplet is discharged onto the substrate P, the drying process is perform if necessary, and then the residue removing treatment may be performed again before the second liquid droplet is discharged onto the substrate P. By performing the residue removing treatment before the second liquid droplet is stacked on the first liquid droplet, the residue remaining on a functional layer, which causes the lyophobic property of the banks to be deteriorated, is removed even when the functional liquid is adhered to the banks so as to deteriorate the lyophobic property of the banks. Therefore, it is possible to achieve the same performance as banks before the next liquid droplet is stacked.

Furthermore, after the baking process is performed, the banks B remaining on the substrate P can be removed by ash peeling treatment. The ashing treatment includes a plasma ashing, ozone ashing, or the like. In the plasma ashing method, a gas, such as oxygen gas in a plasma state, and a bank (resist) is reacted and the bank is vaporized so as to peel off or remove the bank. The bank is a solid material made of carbon, oxygen, and hydrogen. The carbon, oxygen, and hydrogen are chemically reacted with the oxygen plasma so as to become CO₂, H₂O, and O₂, and accordingly, the bank can be peeled off as vapor. On the other hand, the basic principle of the ozone ashing method is the same as that of the plasma ashing method, in which O₃ is divided into O⁺ (oxygen radical), which is a reactive gas, and the O⁺ and the bank is reacted with each other. The bank reacted with the O⁺ becomes CO₂, H₂O, and O₂, peeling off as vapor. As such, by performing the ash peeling treatment on the substrate P, the bank is removed from the substrate P.

As described above, since the process S4 for forming minute irregularities 35a is prepared, the self-flow of ink can be increased and thus minute wiring lines can be easily formed. In addition, the adhesion of the film F is improved due to the irregularities 35a, allowing a highly reliable device to be provided. In addition, since the residue removing process S2 for removing residue is conducted, it is possible to prevent problems, such as a bulge or circuit shortage due to the residue, from occurring and to make liquid droplets of the ink smoothly introduced onto the substrate P. In addition, since the wiring pattern forming ink is disposed on the trenches 34 between the banks B formed on the substrate P, it is possible to prevent the discharged ink from scattering therearound and to easily form the wiring pattern in a predetermined shape according to the shape of the bank.

Electro-Optical Device

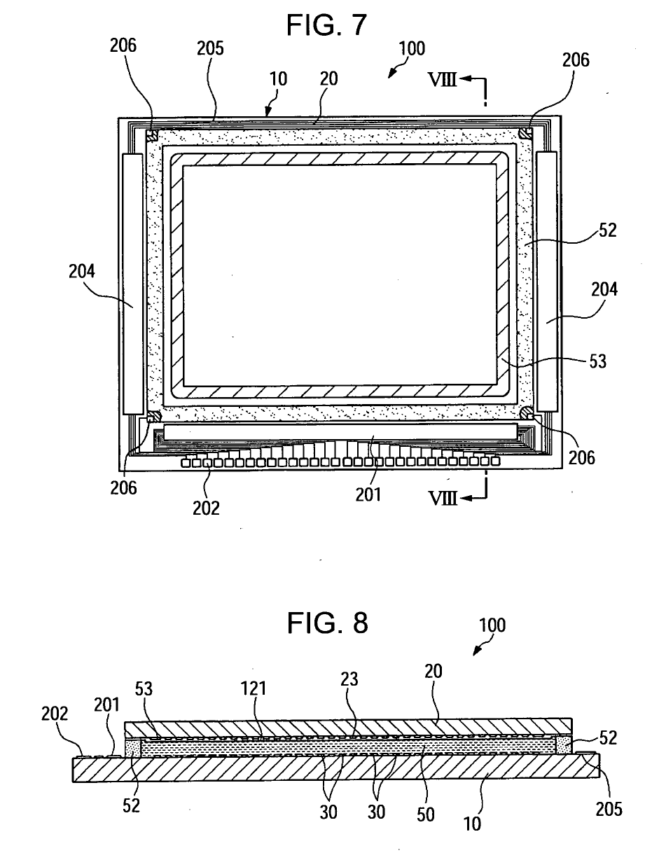

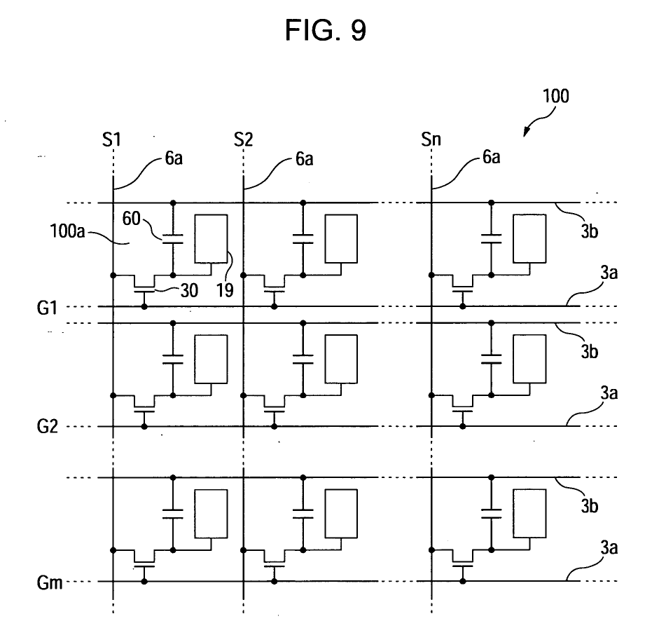

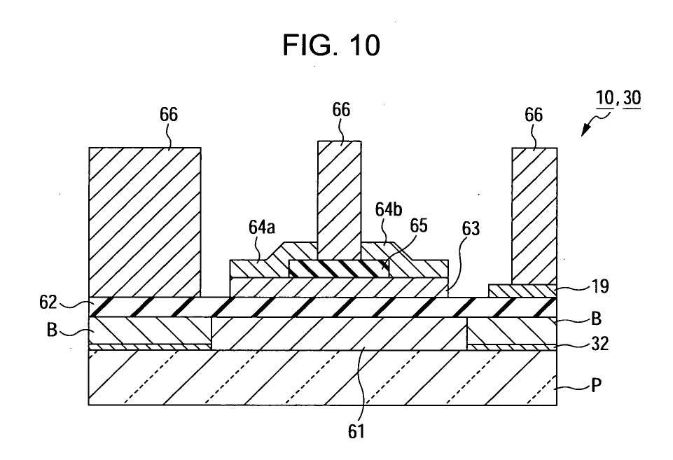

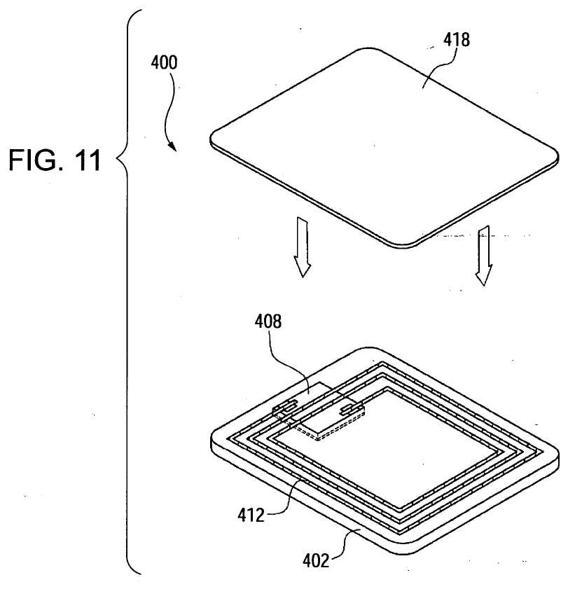

Next, a liquid crystal display device, which is an example of an electro-optical device of the invention, will be described. FIG. 7 is a plan view illustrating various elements of a liquid crystal display device of the invention, when viewed from a counter substrate side, and FIG. 8 is a cross-sectional view taken along the line VIII-VIII of FIG. 7. FIG. 9 is an equivalent circuit diagram of various elements, wiring lines, and so on in a plurality of pixels formed in a matrix in an image display region of the liquid crystal display device, and FIG. 10 is a partially enlarged sectional view of the liquid crystal display device.

In the drawings used for the following description, the scale of each layer or member is adjusted in order to have a recognizable size in the drawings.

As shown in FIGS. 7 and 8, a liquid crystal display device (electro-optical device) 100 according to the present embodiment includes a TFT array substrate 10, a counter substrate 20, which are paired and bonded to each other by a sealant 52 serving as a light-curable end sealant, and liquid crystal 50 sealed and maintained in a region defined by the sealant 52. The sealant 52 has a closed-frame shape in a region of a substrate surface.

A peripheral border 53 formed of a light-shielding material is formed in an inner side of a region where the sealant 52 is formed. In a region outside the sealant 52, a data line driving circuit 201 and mounting terminals 202 are formed along one side of the TFT array substrate 10 and scanning line driving circuits 204 are formed along two sides adjacent to the one side. In the one remaining side of the TFT array substrate 10, a plurality of wiring lines 205, which connects the scanning line driving circuits 204 provided at both sides of the image display region, is provided. In addition, conductive members 206 for making an electrical conduction between the TFT array substrate 10 and the counter substrate 20 are disposed in at least one of the corners of the counter substrate 20.

Further, instead of forming the data line driving circuit 201 and the scanning line driving circuits 204 on the TFT array substrate 10, for example, a TAB (Tape Automated Bonding) substrate having a driving LSI mounted thereon may be electrically and mechanically connected to a group of terminals formed in the periphery of the TFT array substrate 10 through an anisotropic conductive film. In addition, the liquid crystal display device 100 may include a retardation film, a polarizer, and so on (not shown) arranged in a predetermined direction, depending on the kind of the liquid crystal 50 used, that is, an operation mode such as a TN (Twisted Nematic) mode or a STN (Super Twisted Nematic) mode, or a normally white mode/normally black mode. Further, in the case of a liquid crystal display device 100 for color display, for example, red (R), green (G), and blue (B) color filters are formed together with protective films therefore, in a region of the counter substrate 20 opposite to each pixel electrode, which will be described later, of the TFT array substrate 10.

In the image display region of the liquid crystal display device 100 as constructed above, a plurality of pixels 100a are formed in a matrix, the pixels 100a include pixel switching TFTs (switching elements) 30, and data lines 6a for supplying pixel signals S1, S2, . . . , and Sn are electrically, connected to source electrodes of the TFTs 30, respectively, as shown in FIG. 9. The pixel signals S1, S2, and Sn written into the data lines 6a may be sequentially supplied in this order, or may be supplied for each of groups of adjacent data lines 6a. In addition, scanning lines 3a are electrically connected to gate electrodes of the TFTs 30, and scanning signals G1, G2, . . . , and Gm are sequentially applied to the scanning lines 3a in this order at a predetermined timing in a pulsed manner.

Pixel electrodes 19 are electrically connected to drain electrodes of the TFTs 30, and by turning on the TFTs 30 serving as the switching elements for a predetermined period of time, the pixel signals S1, S2, . . . , and Sn supplied from the data lines 6a are written into the pixels at a predetermined timing. The pixel signals S1, S2, . . . , and Sn having predetermined levels and written into the liquid crystal through the pixel electrodes 19 are maintained between the pixel electrodes 19 and a counter electrode 121 of the counter substrate 20 shown in FIG. 8 for a predetermined period of time. In addition, in order to prevent the maintained pixel signals S1, S2, . . . , and Sn from leaking, storage capacitors 60 are added in parallel to liquid crystal capacitors formed between the pixel electrodes 19 and the counter electrode 121. For example, the voltages of the pixel electrodes 19 are maintained by the storage capacitors 60 for a period of time which is 1000 times longer than a period of time for which a source voltage is applied. Accordingly, a storage characteristic of charges is improved, thus realizing a liquid crystal display device 100 having a high contrast ratio.

FIG. 10 is a partially enlarged sectional view of the liquid crystal display device 100 having a bottom-gate-type TFT 30, where a gate wiring line 61 is formed on a glass substrate P forming the TFT array substrate 10 by using the above-described wiring pattern forming method.

On the gate wiring line 61, a semiconductor layer 63 formed of an amorphous silicon (a-Si) layer is stacked with a gate insulating film 62 made of SiNₓ interposed therebetween. A portion of the semiconductor layer 63 opposite to the gate wiring line becomes a channel region. Junction layers 64a and 64b formed of, for example, an n⁺-type a-Si layer to obtain an ohmic contact, are formed on the semiconductor layer 63, and an insulating etching stopper 65 made of SiNₓ to protect a channel is formed on the semiconductor 63 in a central portion of the channel region. In addition, the insulating film 62, the semiconductor layer 63, and the etching stopper 65 are patterned as shown in FIG. 10, by performing resist application, photosensitization development, and photo-etching processes after performing a deposition (CVD) process.

Furthermore, the junction layers 64a and 64b and pixel electrode 19 made of ITO are also formed and patterned, as shown in FIG. 10, by performing a photo-etching process. In addition, banks 66 are formed on the pixel electrode 19, the gate insulating layer 62, and the etching stopper 65, respectively, and the liquid droplets made of silver compound are discharged between the banks 66 by using the liquid droplet discharging apparatus IJ, thereby forming source and drain lines.

While it is shown in the present embodiment that the TFT 30 is used as a switching element for driving the liquid crystal display device 100, this configuration can be applied to an organic EL (electroluminescent) display device, for example, in addition to the liquid crystal display device 100. The organic EL device is a device in which a film containing inorganic and organic fluorescent compounds is interposed between a cathode and an anode, exciton is generated by injecting electrons and holes into the film so as to recombine the electrons and holes, and an image is displayed by using emission of light (fluorescence phosphorescence) when the exciton is deactivated. In addition, a self-emitting full color EL device can be manufactured by patterning ink, which is composed of materials showing red, green, and blue colors, that is, light-emitting layer formation materials, and materials for forming hole injection/electron transport layers, on the substrate having the TFT 30. The scope of device (electro-optical device) in the invention covers the above-described organic EL device.

Next, a non-contact card medium according to another embodiment of the invention will be described. As shown in FIG. 11, a non-contact card medium (electronic apparatus) 400 according to the present embodiment contains a semiconductor integrated circuit chip 408 and an antenna circuit 412 in a casing composed of a card base 402 and a card cover 418, and performs a power supply operation and at least one of data transmission and reception operations through an external transceiver (not shown) and at least one of electromagnetic waves and electrostatic capacitive coupling. In the present embodiment, the antenna circuit 412 is formed by the wiring pattern forming method according to the embodiment.

Further, the device (electro-optical device) according to the invention can also be applied to a PDP (plasma display panel), or a surface-conduction electron-emitter display using a phenomenon that electrons are emitted when current flows in parallel to a surface of a small-area thin film formed on a substrate.

Electronic Apparatus

Next, specific examples of an electronic apparatus of the invention will be described.

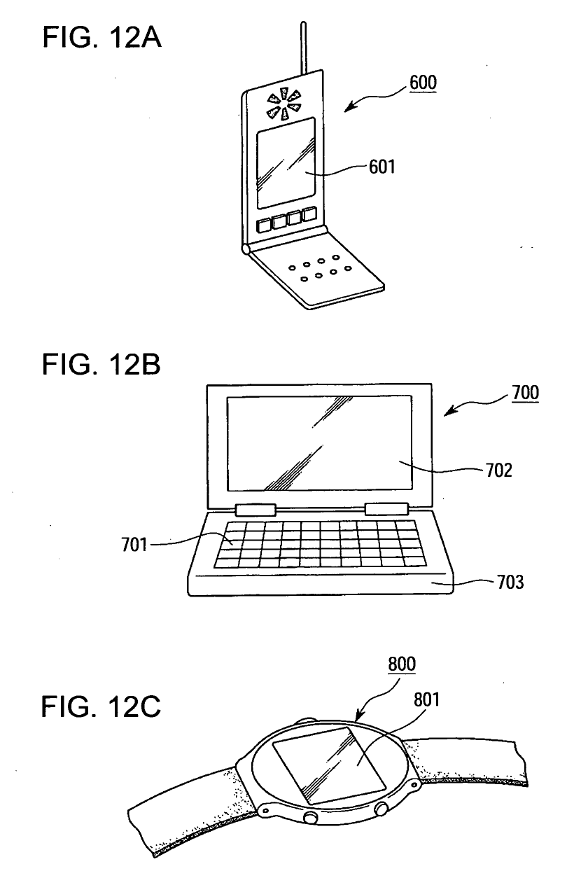

FIG. 12A is a perspective view illustrating an example of a mobile phone. In FIG. 12A, reference numeral 600 denotes a mobile phone body, and reference numeral 601 denotes a liquid crystal display unit including the liquid crystal display device described in the above embodiments.

FIG. 12B is a perspective view illustrating an example of a portable information processing apparatus such as a word processor or a personal computer. In FIG. 12B, reference numeral 700 denotes an information processing apparatus, reference numeral 701 denotes an input unit such as a keyboard, reference numeral 703 denotes an information processing apparatus body, and reference numeral 702 denotes a liquid crystal display unit including the liquid crystal display device described in the above embodiments.

FIG. 12C is a perspective view illustrating an example of an electronic wrist watch. In FIG. 12C, reference numeral 800 denotes a watch body, and reference numeral 801 denotes a liquid crystal display unit including the liquid crystal display device described in the above embodiments.

The electronic apparatuses shown in FIGS. 12A to 12C include the liquid crystal display device described in the above embodiments, in which a problem that wiring lines are short-circuited or the like can be prevented.

Even though it is shown in the embodiments that the electronic apparatuses use the liquid crystal display device, the electronic apparatuses may use other electro-optical devices such as organic EL display devices or plasma display devices.

Having described the preferred embodiments of the invention with reference to the accompanying drawings, the invention is not limited thereto. It should be noted that various shapes or combinations of various members or elements described in the embodiments are only illustrative, but the members or elements and combinations thereof may be properly changed in various ways as a design demands without departing from the scope and spirit of the invention.

For example, even though the film pattern is constructed by the conductive film in the embodiments, the invention is not limited thereto but can be applied to a color filter used to colorize display images in the liquid crystal display device, for example. The color filter can be formed by disposing red (R), green (G), and blue (B) ink (liquid materials) on a substrate in the form of liquid droplets and in a predetermined pattern; however, it is possible to manufacture a liquid crystal display device having a highly reliable color filter by forming banks according to a predetermined pattern on a substrate, forming minute irregularities on bottoms of trenches formed between the banks, and disposing ink thereon.

What is claimed is:

1. A method of forming a film pattern by disposing a functional liquid on a substrate, comprising:
forming banks corresponding to the film pattern on the substrate;
forming irregularities on bottom surfaces between the banks by using the banks as a mask; and
disposing the functional liquid between the banks and on the bottom surfaces formed with the irregularities.

2. The method according to claim 1,
wherein the step of forming the irregularities includes etching a surface of the substrate between the banks by using the banks as a mask.

3. The method according to claim 2, comprising:
fluorinating surfaces of the banks before forming the irregularities.

4. The method according to claim 1,
wherein the functional liquid is rendered conductive by performing at least one of heat treatment and optical treatment.

5. A method of manufacturing a device, comprising:
forming a film pattern on a substrate,
wherein the film pattern is formed on the substrate by using the method of forming the film pattern according to claim 1.

6. An electro-optical device comprising the device manufactured by using the method of manufacturing the device according to claim 5.

7. An electronic apparatus comprising the electron optical device according to claim 6.

8. A method of forming a film pattern on a substrate, the method comprising:
forming spaced apart banks on the substrate, the banks and a surface of the substrate between the banks defining a trench on the substrate corresponding to the film pattern;
after forming the banks, forming irregularities on the surface of the substrate between the banks by using the banks as a mask; and
disposing a functional liquid on the surface of the substrate between the banks formed with the irregularities.

9. The method according to claim 8, wherein the step of forming the irregularities includes etching the surface of the substrate between the banks.

10. The method according to claim 8, comprising:
fluorinating the banks before forming the irregularities.
